(19) United States
(12) Patent Application Publication
(10) Pub. No.: US 2002/0075641 A1
(43) Pub. Date: Jun. 20, 2002

(54) Mouse pad fixing structure

(76) Inventor: Chung Shen Liu, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/738,996

(22) Filed: Dec. 19, 2000

(51) Int. Cl. H05K 5/00

(52) U.S. Cl. 361/686

(57) ABSTRACT

A structure for fixing a mouse pad in a notebook computer includes a resilient post extending from a bottom of the mouse pad. The post extends through a hole defined a circuit board contained in the notebook computer. The post has a free end abutting a portion of the notebook computer. The free end is expanded and defines a circumferential shoulder engaging with an underside of the circuit board thereby securely fixing the mouse pad in the computer while allowing readily mounting/dismounting of the mouse pad to/from the computer.

### FIELD OF THE INVENTION

The present invention generally relates to a mouse pad of a notebook computer, and in particular to a structure for fixing a mouse pad in a notebook computer.

### BACKGROUND OF THE INVENTION

A mouse pad is incorporated in a notebook computer for facilitating user's control of display cursor. The mouse pad is usually fixed in a top face of a base portion of a notebook computer. The conventional way for mounting the mouse pad to the notebook is quite cumbersome. So does dismount the mouse pad from the notebook computer. Thus, the cost for mounting/dismounting the mouse pad is high.

It is thus desirable to overcome such a problem for simplifying mounting/dismounting a mouse pad and reducing the costs thereof.

### SUMMARY OF THE INVENTION

Accordingly, an object of the present invention is to provide a mouse pad fixing structure for readily mounting/dismounting a mouse pad to/from a notebook computer.

Another object of the present invention is to provide a structure for lowering manufacturing costs of notebook computers.

To achieve the above objects, in accordance with the present invention, there is provided a structure for fixing a mouse pad in a notebook computer comprising a resilient post extending from a bottom of the mouse pad. The post extends through a hole defined a circuit board contained in the notebook computer. The post has a free end abutting a portion of the notebook computer. The free end is expanded and defines a circumferential shoulder engaging with an underside of the circuit board thereby securely fixing the mouse pad in the computer while allowing readily mounting/dismounting of the mouse pad to/from the computer.

### BRIEF DESCRIPTION OF THE DRAWINGS

The present invention will be apparent to those skilled in the art by reading the following description of a preferred embodiment thereof, with reference to the attached drawings, in which:

FIG. 1 is a perspective view showing a notebook computer in which a mouse pad fixing structure in accordance with the present invention is incorporated; and

FIG. 2 is a cross-sectional view of a portion of the notebook computer showing the mouse pad fixing structure of the present invention.

### DETAILED DESCRIPTION OF THE PREFERRED EMBODIMENT

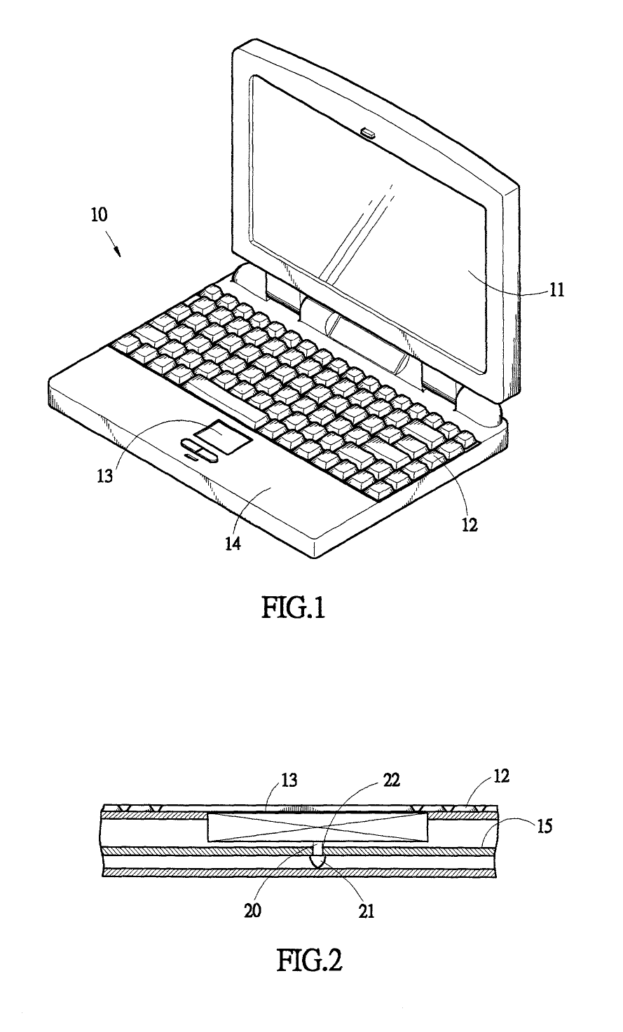

FIG. 1 shows a notebook computer 10 including a display 11, a keyboard 12 and a mouse pad 13. The notebook computer 10 comprises a base portion 14 and a cover portion (not labeled) pivoted to the base portion 14. The display 11 is formed on the cover portion while the keyboard 12 and the mouse pad 13 are formed on a top wall of the base portion 14. A fixing structure in accordance with the present invention is incorporated in the base portion 14 for securely fixing the mouse pad 13 in position.

Also referring to FIG. 2, which shows a cross-sectional view of a portion of the base portion 14, the fixing structure of the present invention comprises a post 20 extending from a bottom of the mouse pad 13 toward a bottom wall of the base portion 14. The post 20 extends through a positioning hole 22 defined in a circuit board 15 received and fixed in a spaced defined between the top and bottom walls of the base portion 14 of the notebook computer 10. The post 20 has a length sufficient to have a free end 21 thereof engaging and abutting the bottom wall of the base portion 14 thereby supporting the mouse pad 13 in position. Preferably, the free end 21 is expanded forming a circumferential shoulder (not labeled) engaging an underside of the circuit board 15 for firmly retaining the mouse pad 13 in position.

Preferably, the post 20 is made of a resilient material, such as rubber which allows the post 20 to be readily mounted to the base portion 14. The resiliency of the post 20 allows the post 20 to be extended through the hole 22 for readily mounting/dismounting the mouse pad 13 to/from the base portion 14. The structure can be readily adapted to different designs/specifications of notebook computers for only a single hole is needed to be formed on the circuit board.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A structure for fixing a mouse pad to a notebook computer, the structure comprising:
a post extending from a bottom of a mouse pad in the base portion, and
a hole defined in the notebook computer through which the post extends for securely engaging therewith.

2. The structure as claimed in claim 1, wherein the post has a free end abutting against a portion of the notebook computer.

3. The structure as claimed in claim 1, wherein the hole is defined in a plate-like structure of the notebook computer and wherein the post has an expanded end forming a shoulder engaging with a surface of the plate like structure for securely retaining the post in position.

4. The structure as claimed in claim 1, wherein the post is made of a resilient material.

5. The structure as claimed in claim 4, wherein the resilient material is rubber.

6. The structure as claimed in claim 1, wherein the notebook computer comprises a base portion having a top wall and a bottom wall defining a space therebetween for receiving a circuit board, the mouse pad being mounted on the top wall with the post extending toward the bottom wall, the post having a free end abutting and engaging the bottom wall, the hole being defined in the circuit board through which the post extends.

7. The structure as claimed in claim 6, wherein the free end of the post is expanded forming a circumferential shoulder engaging with an underside of the circuit board.

8. The structure as claimed in claim 7, wherein the post is made of rubber.
